(19) United States
(12) Patent Application Publication
(10) Pub. No.: US 2005/0105577 A1
(43) Pub. Date: May 19, 2005

(54) Semiconductor laser device and manufacturing method for the same

(75) Inventors: Toshiya Fukuhisa, Matsubara-shi (JP); Hidetoshi Furukawa, Suita-shi (JP)

Correspondence Address: MERCHANT & GOULD PC, P.O. BOX 2903, MINNEAPOLIS, MN, 55402-0903, US

(73) Assignee: MATSUSHITA ELECTRIC INDUSTRIAL CO., LTD., Kadoma-shi (JP)

(21) Appl. No.: 10/979,273

(22) Filed: Nov. 2, 2004

(30) Foreign Application Priority Data
Nov. 13, 2003 (JP) 2003-383908

(51) Int. Cl. H01S 5/00

(52) U.S. Cl. 372/50; 372/68; 372/45; 372/46

(57) ABSTRACT

The present invention provides a semiconductor laser that includes a substrate and at least two active layers, wherein two resonators that respectively include the active layers are mutually arranged in parallel, and wherein in the resonators, the region of the active layers into which a current is injected, have different lengths. Thus, in the two wavelength laser of the present invention, by overcoming the limitation of the lengths of the resonators that are determined by the cleavages, it is possible to independently design and manufacture effective resonator lengths of a plurality of lasers of different characteristics, such as red lasers and infrared lasers, employ resonator lengths that are suitable for the respective desired characteristics, and provide a semiconductor with improved laser characteristics.

### FIELD OF THE INVENTION

The present invention relates to semiconductor laser devices used in DVD-RAM (digital versatile disk random access memory), DVD-R (digital versatile disk recordable), DVD-RW (digital versatile disk rewritable), DVD+R, DVD+RW, CD-R (compact disk recordable), CD-RW, DVD-ROM (digital versatile disk read only memory), CD-ROM, DVD-Video, CD-DA and other optical disk devices, or for such uses as optical information processing, optical communication or optical measurement, and to methods for manufacturing the same.

### BACKGROUND OF THE INVENTION

AlGaInP-based red lasers with a wavelength in the region of 650 nm are used as the reading and writing pickup light source of, for example, DVD-RAMs. On the other hand, AlGaAs-based infrared lasers with a wavelength in the region of 780 nm are used as the reading and writing pickup light source of, for example, CD-Rs. In order to handle both disks, it is necessary to provide both red and infrared lasers in a single drive. Thus, there is now widespread use of drives that are provided with two integrated optical units, for DVD use and for CD use.

However, due to the demand in recent years for miniaturization, lower costs and simpler optical system assembly processes, there is an increasing tendency toward commercial application of two-wavelength lasers, so as to address these demands with a single integrated optic unit, in which two lasers are integrated on a single substrate. JP 2000-11417A is a conventional example of such a two-wavelength laser. This proposes a monolithic laser in which an AlGaInP-based red laser of a wavelength region of 650 nm and an AlGaAs-based infrared laser of a wavelength region of 780 nm are integrated monolithically on a GaAs substrate, wherein an optical pickup that is provided with lasers for both CD and DVD is provided on a single integrated optical unit.

In a similar way as with conventional lasers, for two-wavelength lasers, the resonator is formed by cleaving. Since the length of the resonator is determined by the position of the cleavage at both ends, the red laser and the infrared laser naturally have the same resonator length. The length of the resonator is one of the parameters that affect laser characteristics such as maximum light output, threshold oscillating current and efficiency. However, in the case of two-wavelength lasers, there is a limitation in that it is not possible to optimize the red laser and the infrared laser independently.

For example, in a laser in which a high power red laser and a high power infrared laser are monolithically integrated, if the high power of 200 mW of the red laser is to be realized, then in practice the length of the resonator is necessarily at least 900 μm. However, when the length of the resonator of the infrared laser is at least 900 μm, the operating current increases to greater than that of a conventional laser, there is an increase in power consumption, and there is concern over deleterious effects such as accelerated thermal degradation of components. Thus, because of this situation, it may be difficult to increase the output of two-wavelength lasers.

### SUMMARY OF THE INVENTION

A semiconductor laser device of the present invention is provided with a substrate and at least two active layers, wherein two resonators that respectively include the active layers are mutually arranged in parallel, and wherein in the resonators, the regions of the active layers into which a current is injected have different lengths.

A method for manufacturing a semiconductor laser device of the present invention is provided by a step of sequentially layering a first-type cladding layer of a first conductivity type, a first active layer and a first cladding layer of a second conductivity type on a substrate to form a first layered structure, a step of removing the first layered structure from a predetermined region of the substrate, a step of sequentially layering a second cladding layer of the first conductivity type, a second active layer and a second cladding layer of the second conductivity type above the substrate that includes the first layered structure to form a second layered structure, a step of removing the second layered structure that is formed above the first layered structure, a step of forming a layer made of an impurity diffusion source in a predetermined region above the first layered structure and the second layered structure, and a step of heating the substrate and diffusing impurities from the layer that is made of an impurity diffusion source into the first layered structure and the second layered structure that are directly below it to disorder a part of at least either the first active layer or the second active layer, wherein the resonator direction width of the region of the first layered structure into which impurities are diffused and the resonator direction width of the region of the second layered structure into which impurities are diffused are mutually different.

### BRIEF DESCRIPTION OF THE DRAWINGS

FIG. 1A is a cross-sectional view of a two-wavelength laser of Embodiment 1 of the present invention, FIG. 1B is a cross-sectional view across the I-I line of FIG. 1A, and FIG. 1C is a cross-sectional view across the II-II line of FIG. 1A.

FIG. 2 is a perspective view of the two-wavelength laser of Embodiment 1 of the present invention.

FIGS. 3A to 3D are cross-sectional views of a manufacturing process of the two-wavelength laser of Embodiment 1 of the present invention.

FIGS. 4A to 4B are cross-sectional views of the manufacturing process of the two-wavelength laser of Embodiment 1 of the present invention, and FIG. 4A′ to 4B′ are plan views of the same.

FIGS. 5A to 5D are cross-sectional views of the manufacturing process of the two-wavelength laser of Embodiment 1 of the present invention.

FIG. 6 is a graph of current vs. light output characteristics of a two-wavelength laser of a resonator length of 700 μm.

FIG. 7 is a graph of current vs. light output characteristics of a two-wavelength laser of a resonator length of 1000 μm.

FIG. 8 is a graph of current vs. light output characteristics of the two-wavelength laser of Embodiment 1 of the present invention.

FIG. 9A is a plan view of a high power and low power red laser monolithic integrated chip of Embodiment 2 of the present invention, FIG. 9B is a cross-sectional view across the III-III line of FIG. 9A, and FIG. 9C is a cross-sectional view across the IV-IV line of FIG. 9A.

FIGS. 10A to 10E are cross-sectional views of a manufacturing process of a high power and low power red laser monolithic integrated chip of Embodiment 2 of the present invention.

FIG. 11 is a graph of current vs. light output characteristics of the two-wavelength laser of Embodiment 2 of the present invention.

### DETAILED DESCRIPTION OF THE INVENTION

For a two-wavelength laser according to the present invention, by adopting a structure that blocks electric current from being injected into an active layer in one part of a region from either one, or both, facets of the laser toward the center of the resonator, it becomes possible to control the respective lengths of the effective resonator length independently, that is to say, the length in the resonator direction of the active layer that contributes to laser oscillation. Thus, the optimum setting of the length of the resonator of the red and the infrared laser is realized, and it is possible to improve the laser characteristics.

In the present invention, if the length of the resonator in the region in which current is supplied to the active layer is 1000 μm for the red laser and 700 μm for the infrared laser, then it is possible to realize a device in which each has desirable operating current, light output and temperature characteristics.

In the present invention, it is preferable that parallelism between “two resonators mutually arranged in parallel” tolerates a deviation of not more than ±1 degree therefrom.

It is preferable that at least one of the active layers is constituted by a quantum well. By providing a quantum well, in addition to having the same effect as a conventional laser, namely a reduction in the operating current density due to an increase in light emitting efficiency with respect to the injection carrier, since a band gap increase occurs due to crystal disorder if Zn diffusion is performed with a quantum well structure, if this is applied to a non-gain region (a region in which current is not injected) of an element whose effective resonator length is short, then it is possible to prevent deterioration of the characteristics, such as an increase in operating current caused by light absorption.

It is preferable that in a part of a region that extends from one or both facets toward the center of at least one resonator, a region is formed in which current is not injected into the active layer, and that by mutually differentiating the lengths of the regions in which current is not injected between the two resonators, the length of the regions in the resonator direction of the active layer into which current is injected is differentiated. This is because, since carrier confinement is weaker and thermal resistance is larger with red lasers than infrared lasers, and thus the limit of light output due to thermal saturation is low, it is necessary to achieve improved temperature characteristics and high power due to improvements in the facet reflectance loss and heat dissipation by increasing the length of the resonator. On the other hand, when the length of the resonator of the infrared laser is increased to the same length as that of the red laser, the operating current increases significantly over that of the conventional single wavelength laser due to an increase in the light emitting area.

It is preferable that a band gap energy of a semiconductor layer of a region in which light is propagated in the region in which current is not injected into the active layer is greater than the energy of the wavelength of the light that is emitted at the active layer. This is because when the band gap region is smaller than the energy of the wavelength of the light that is emitted by the active layer, light absorption occurs, and this gives rise to a worsening of characteristics such as increase in the threshold current and the operating current, and loss of light output.

It is preferable that the two active layers are constituted respectively by layers that include (AlₓGa₁₋ₓ)_{y}In_{1-y}P (where 0≦x≦1 and 0≦y≦1) and Al_{z}Ga_{1-z}As (where 0≦z≦1), and that the wavelengths that are obtained from the two active layers are respectively at least 630 nm and at most 690 nm, and at least 760 nm and at most 810 nm. This is due to the fact that laser light in these wavelength bands is necessary for reading from and writing to DVD type optical disks and CD type optical disks.

It is preferable that the maximum light output that is emitted from a single face that is obtained from the two active layers is at least 80 mW. This is the light output necessary to write data onto the optical disks at at least double speed.

It is preferable that a band gap of at least one part of the quantum well active layer of at least one resonator, in the direction from one or both facets toward the center of the resonator, is broadened by disorder through diffusion of impurities or injection of impurities, that a current blocking layer is provided, or a part of the semiconductor layer or an electrode that corresponds to a current injection path is removed such that the current is not injected and that the length over which the process is performed from the facet toward the center of the resonator, mutually differs between the two resonators. By employing such a manufacturing method, the interval between light emitting facets can be controlled accurately, and it is possible to form elements in which each has an optimum resonator length.

It is preferable that at least two of the active layers are constituted by layers that include (AlₓGa₁₋ₓ)_{y}In_{1-y}P (where 0≦x≦1 and 0≦y≦1), and that of the two active layers, the light output of the element with the higher maximum light output is at least 50 mW, and the operating current of the element with the lower output is at most 35 mA at a light power of at least 2 mW. By setting one element to be the high power laser that is capable of writing to disks, and the other element to be the low power laser that is capable of reading disks at low operating current, since the power consumption when reading data can be decreased to lower than that of a conventional optical disk apparatus that uses a single high power laser to both read from and write to the optical disk, the development of products such as portable DVDs is facilitated.

In the two-wavelength laser according to the present invention, by overcoming the limitation of the length of the resonator that is determined by the cleavages, it is possible to independently design and manufacture effective resonator lengths of a plurality of lasers of different characteristics, such as red lasers and infrared lasers, and thus it is possible to improve the characteristics of the lasers by employing resonator lengths that are suitable for the respective desired characteristics.

Embodiments of the present invention are described below.

### Embodiment 1

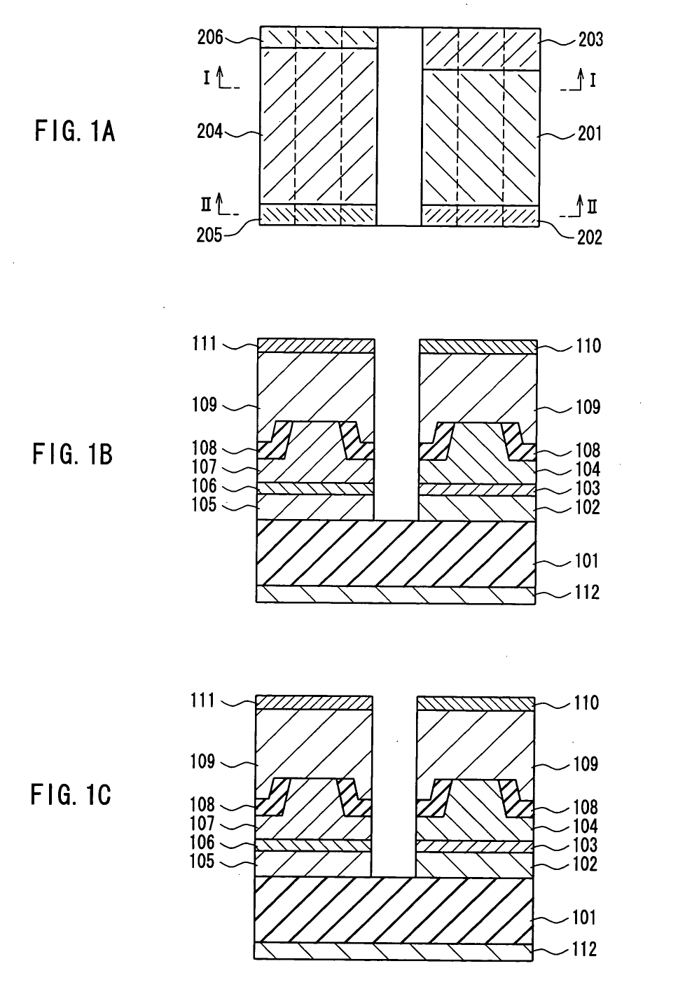

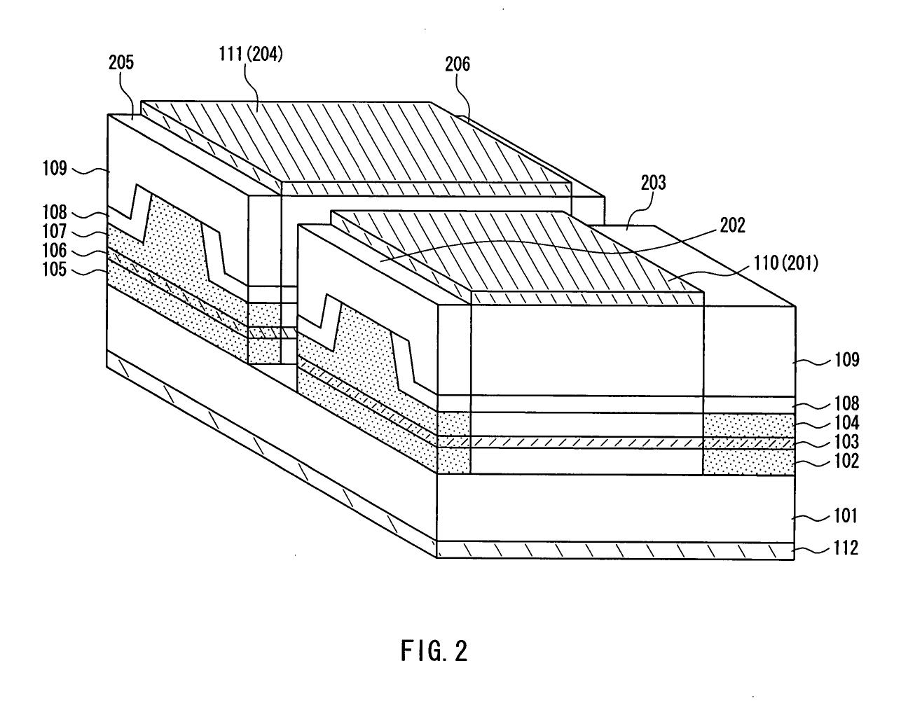

FIGS. 1A to 1C and FIG. 2 show a 200 mW class optical output two-wavelength high power laser of Embodiment 1 of the present invention. FIG. 1A is a plan view of the same, FIG. 1B is a cross-sectional view across the I-I line of FIG. 1A, FIG. 1C is a cross-sectional view across the line II-II of FIG. 1A, and FIG. 2 is a perspective view of the same. Similar symbols indicate similar materials or parts.

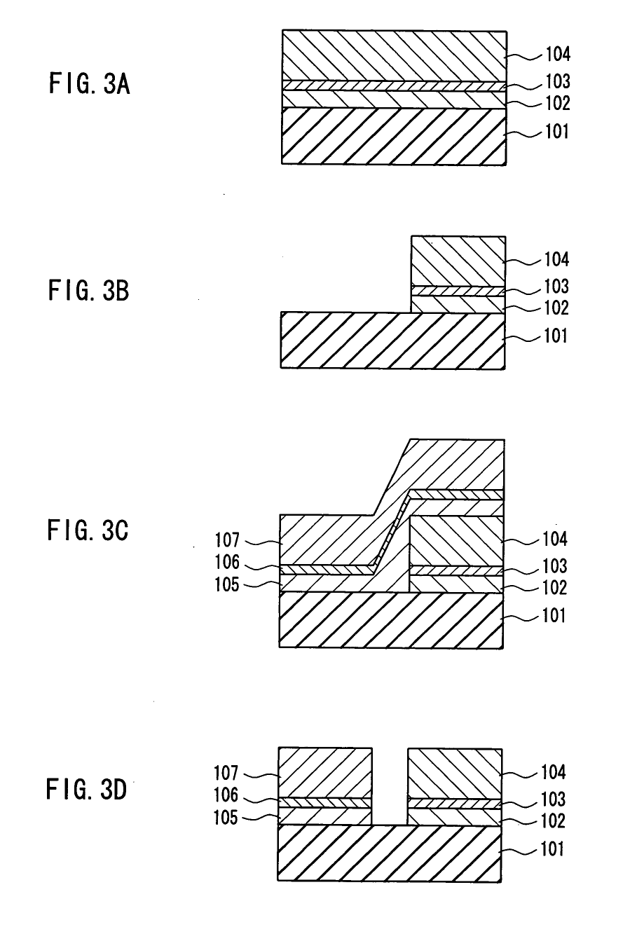

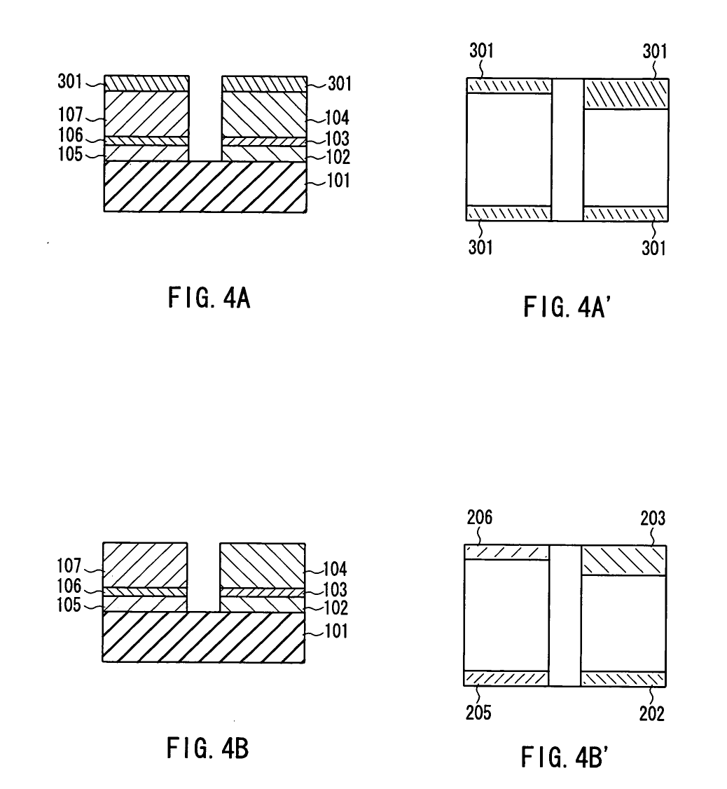

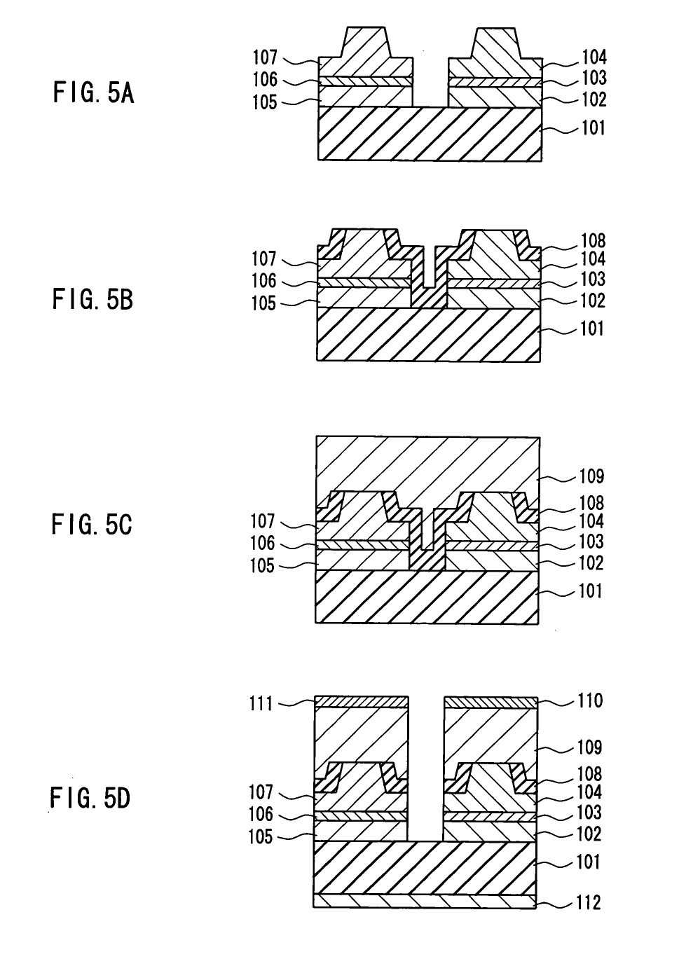

FIGS. 3A to 3D, FIGS. 4A to 4B′ and FIGS. 5A to 5D are cross-sectional views showing a manufacturing process of the semiconductor laser of Embodiment 1 of the present invention (however, FIGS. 4A′ and 4B′ are plan views). The manufacturing process is described here following FIG. 3 to FIG. 5.

(1) As shown in FIG. 3A, an infrared laser n-type cladding layer 102, an infrared laser active layer 103 and an infrared laser p-type cladding layer 104 are sequentially layered on an n-type GaAs substrate 101. The infrared layer active laser 103 is constituted by a quantum well structure.

(2) As shown in FIG. 3B, the infrared laser n-type cladding layer 102, the infrared laser active layer 103 and the infrared laser p-type cladding layer 104 are removed from one part of a region that includes a red laser region.

(3) As shown in FIG. 3C, a red laser n-type cladding layer 105, a red laser active layer 106 and a red laser p-type cladding layer 107 are sequentially layered. The red laser active layer 106 is constituted by a quantum well structure.

(4) As shown in FIG. 3D, the red laser n-type cladding layer 105, the red laser active layer 106 and the red laser p-type cladding layer 107 are removed from part of a region that includes an infrared laser region.

(5) As shown in FIGS. 4A and 4A, a zinc oxide film 301 is formed in a region up to 10 μm from both end faces of the red laser p-type cladding layer 107, and in a region up to 10 μm and 310 μm respectively from the end faces of the infrared laser p-type cladding layer 104.

(6) As shown in FIGS. 4B and 4B′, by heating the regions 202, 203, 205 and 206 that are formed by the zinc oxide film, Zn is diffused into the active layer that is directly below each. By this process, the band gap is widened by disordering the heterojunction of the quantum well layer forming the active layer and the barrier layers adjacent thereto. This region is transparent to wavelengths of light emitted from the active layer. The zinc oxide film is removed after heating. The lengths of the regions 201 and 204 are 680 μm and 980 μm respectively.

(7) As shown in FIG. 5A, a part of the infrared laser p-type cladding layer 104 and the red laser p-type cladding layer 107 are etched to form a stripe-shaped mesa structure on each. The width of the upper portion of the mesa is 1 μm and the width of the lower portion is 3 μm.

(8) A current blocking layer 108 is selectively regrown as shown in FIG. 5B.

(9) Regrowth of a contact layer 109 is performed as shown in FIG. 5C.

(10) As shown in FIG. 5D, the vicinity of the border between the infrared laser and the red laser is etched down to the substrate 101 to separate the elements. p-side electrodes 110 and 111 are formed on the infrared laser in the region that excludes the regions 202 and 203, and on the red laser in the region that excludes the regions 205 and 206. Moreover, an n-side electrode 112 is vapor deposited onto a lower portion of the substrate, forming an element.

It should be noted that the material, conductivity type, film thickness and carrier concentration of each layer is as given in Table 1.

TABLE 1

| | | Conductivity | Film | |
|---|---|---|---|---|
| Layer | Material | type | thickness | Carrier conc. |
| substrate 101 | GaAs:Si | N | | 1 × 10¹⁸ cm⁻³ |
| infrared laser n-type | (Al_{0.7}Ga_{0.3})_{0.5}In_{0.5}P:Si | N | 1.0 μm | 1 × 10¹⁸ cm⁻³ |
| cladding layer 102 | | | | |
| infrared laser active | GaAs/Al_{0.4}Ga_{0.6}As quantum well | | | |
| layer 103 | | | | |
| infrared laser p-type | (Al_{0.7}Ga_{0.3})_{0.5}In_{0.5}P:Zn | P | #1) | 5 × 10¹⁷ cm⁻³ |
| cladding layer 104 | | | | |
| red laser n-type | (Al_{0.7}Ga_{0.3})_{0.5}In_{0.5}P:Si | N | 1.0 μm | 1 × 10¹⁸ cm⁻³ |
| cladding layer 105 | | | | |
| red laser active | Ga_{0.45}In_{0.55}P/(Al_{0.5}Ga_{0.5})_{0.5}In_{0.5}P quantum well | | | |
| layer 106 | | | | |
| red laser p-type | (Al_{0.7}Ga_{0.3})_{0.5}In_{0.5}P:Zn | P | #1) | 3 × 10¹⁷ cm⁻³ |
| cladding layer 107 | | | | |
| current blocking | Al_{0.5}In_{0.5}P:Si | N | 0.35 μm #2) | 1 × 10¹⁸ cm⁻³ |
| layer 108 | | | | |
| contact layer 109 | GaAs:Zn | P | 2.5 μm | 1 × 10¹⁹ cm⁻³ |

(remarks)
#1) The inner portion of the mesa is 1.4 μm, the outer portion of the mesa is 0.2 μm.
#2) This is the film thickness grown in the region, in the direction perpendicular to the substrate.

The present invention provides a difference in resonator direction length of the current injection region 201 of the infrared laser and the current injection region 204 of the red laser.

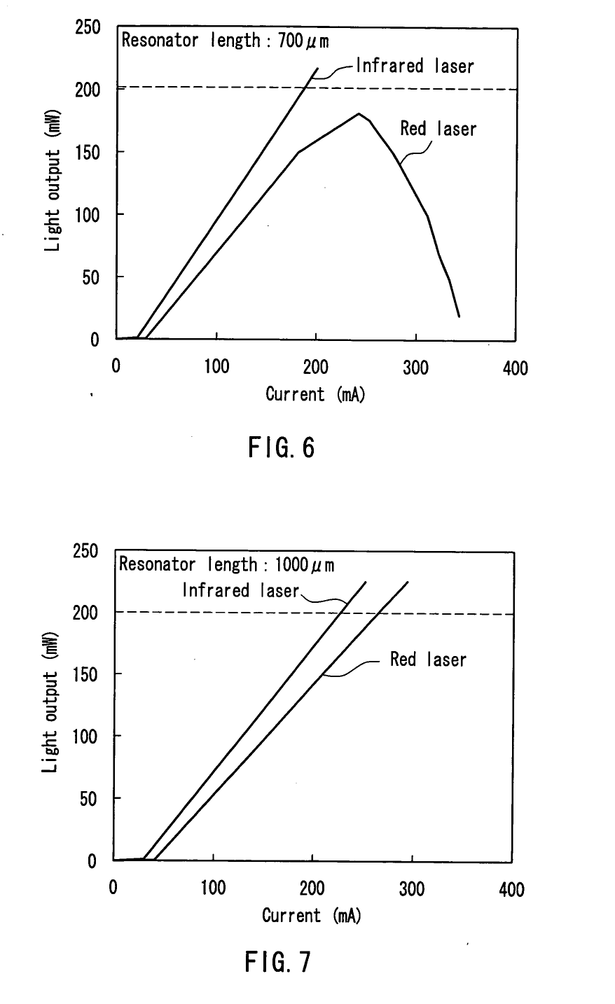

In the case of conventional two-wavelength lasers, the length of the resonator of the infrared laser and the red laser is the same. FIG. 6 shows the current vs. light output characteristics of a red laser and an infrared laser of a two-wavelength laser when the length of both resonators is 700 μm. The desired light output of the red laser cannot be obtained because of thermal saturation in the vicinity of 180 mW. In order to obtain light output of more than 200 mW, it is necessary to increase the length of the resonator of the red light laser.

On the other hand, FIG. 7 shows the current vs. light output characteristics of a red laser and an infrared laser of the two-wavelength laser when the length of both resonators is 1000 μm. Both the infrared laser and the red laser achieve a light output of more than 200 mW, however due to increased volume of the active layer, the operating current of the infrared laser is more than that of the laser whose resonator length is 700 μm. Thus, when mounted in a battery driven portable device, the time in which battery operation is possible is shorter than in a device in which separate lasers are used, because of increased electric power consumption.

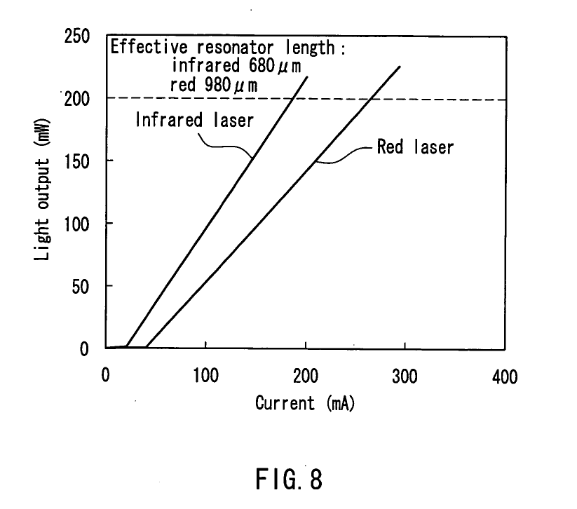

In this embodiment, the effective resonator length of the infrared laser and the red laser is 680 μm and 980 μm respectively. The actual length of the resonator of the infrared laser is 1000 μm, however a region in which current is not injected is provided up to 310 μm from one facet, and up to 10 μm from the other facet, and thus there is also no guide wave loss caused by light absorption since these regions do not contribute to light emission and the band gap widens due to disordering of the quantum well active layer. As a result, as shown in FIG. 8, while the red laser achieves a light output of 200 mW, the operating current of the infrared laser shows a value that is comparable to that of an element with a resonator length of 700 μm. It should be noted that a non-current injection region and a disordered active layer region are provided in the regions within 10 μm of both faces of the red laser. However, these are provided in order to avoid optical breakdown caused by light absorption at the facet.

### Embodiment 2

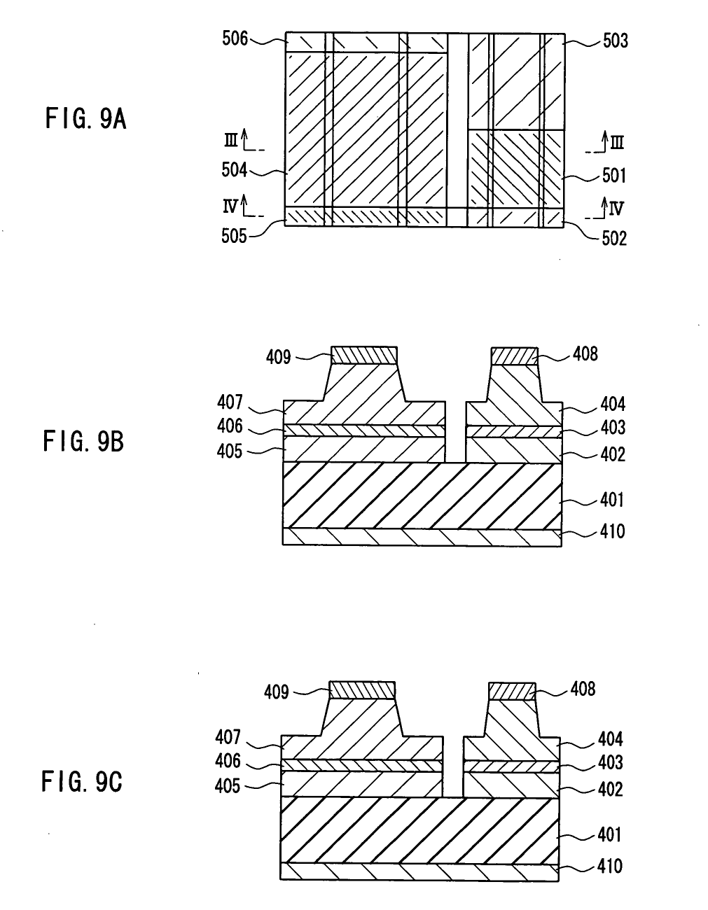

FIG. 9A is a plan view of a high power/low power monolithic red laser of Embodiment 2 of the present invention, FIG. 9B is a cross-sectional view across the line III-III of FIG. 9A, and FIG. 9C is a cross-sectional view across the line IV-IV of FIG. 9A.

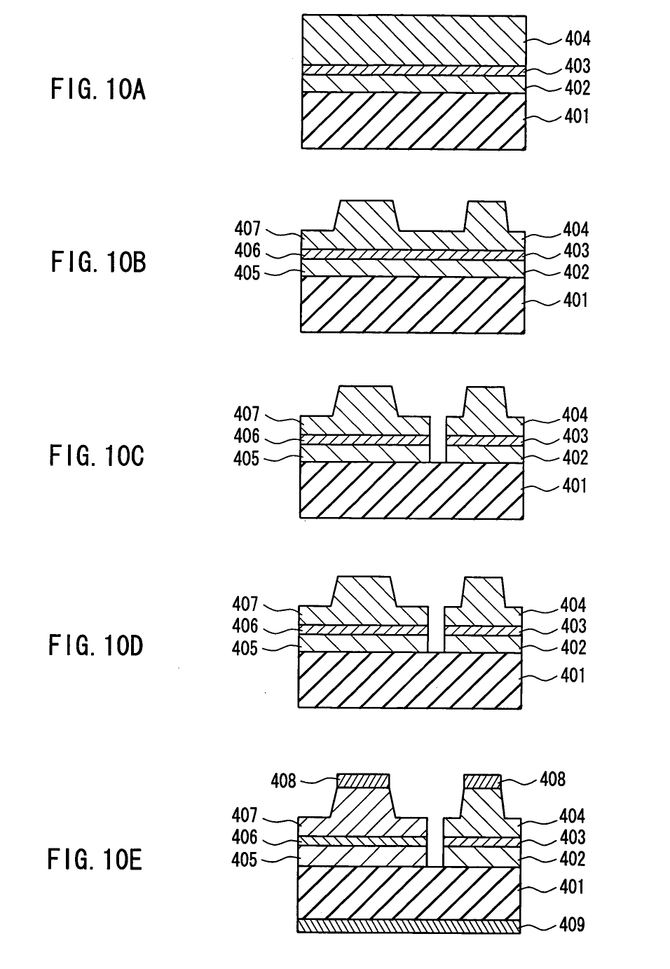

FIGS. 10A to E are cross-sectional structural views showing a manufacturing process of a semiconductor laser of Embodiment 2 of the present invention. The manufacturing process in FIGS. 10A-E is hereby described.

(1) As shown in FIG. 10A, a low power laser n-type cladding layer 402, an active layer 403 and a p-type cladding layer 404 are sequentially layered onto an n-type GaAs substrate 401. The active layer 403 is constituted by a quantum well structure. It should be noted that an n-type cladding layer 405, an active layer 406 and a p-type cladding layer 407 of the high power laser of this embodiment are similar respectively to the layers previously described.

(2) As shown in FIG. 10B, a part of the p-type cladding layers 404 and 407 are etched to form a ridge-type wave guide path.

(3) As shown in FIG. 10C, a part of the p-type cladding layers 404 and 407 are further etched to the substrate 301, separating the elements of the low power laser and the high output laser. In this embodiment, the width of the resonator of the low power laser is less than the width of the resonator of the high-output laser in order to reduce the operating current of the low power laser.

(4) As shown in FIG. 10D, Zn is diffused into the active layer directly below the regions indicated by the numerals 502, 503, 505 and 506 in FIG. 9. The length of the region 501 and 504 of FIG. 9 is 480 μm and 980 μm respectively.

(5) A p-side electrode 408 and an n-side electrode 409 are formed as shown in FIG. 10E.

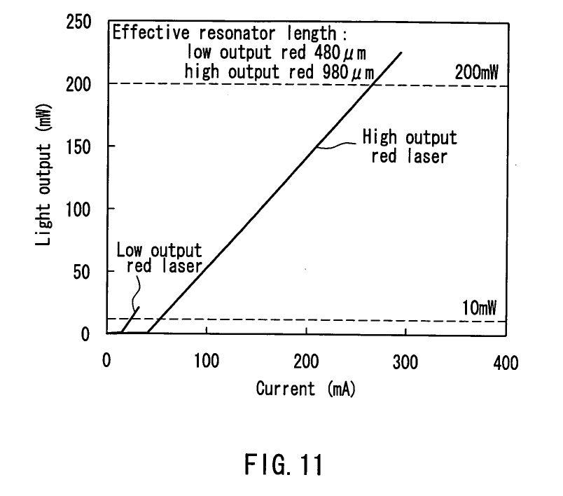

The graph of current vs. light output characteristics of this element is shown in FIG. 11. On the one hand, the high-output laser realizes a light output of greater than 200 mW, and on the other, the low power laser achieves the 10 mW light output that is necessary for reading at a low operating current, by a current in the order of 20 mA.

The conventional high power red laser for rewriting DVDs has a resonator length that is long, and thus when operating at a low power for reading data the operating current is higher than that of a low power, read-only red laser whose resonator length is short. However, as shown in this embodiment, by monolithically integrating two red lasers whose effective resonator lengths are different, and using the high power laser, whose resonator length is long, for writing data, and the low power laser, whose resonator length is short, for reading data, it is possible to read data with an optical pickup that has a lower than conventional power consumption without losing data writing capability.

In this manner, the present invention is not limited to two-wavelength lasers, but is also capable of being applied to monolithic integration of lasers of similar wavelengths.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

1. A semiconductor laser device, comprising:
a substrate; and
at least two active layers,
wherein two resonators that respectively include the active layers are mutually arranged in parallel; and
wherein in the resonators, the regions of the active layers into which a current is injected have different lengths.

2. The semiconductor laser device according to claim 1,
wherein the wavelength of the emitted light that is obtained from the at least two active layers respectively differs.

3. The semiconductor laser device according to claim 2,
wherein at least one of the active layers is constituted by a quantum well.

4. The semiconductor laser device according to claim 1,
wherein the two resonators have facets at ends in a length direction of the resonators,
wherein in a part of a region that extends from one or both facets toward the center of at least one resonator, a region is formed in which current is not injected into the active layer, and
wherein by mutually differentiating the lengths of the regions in which current is not injected between the two resonators, the length of the regions in the resonator direction of the active layer into which current is injected is differentiated.

5. The semiconductor laser device according to claim 4,
wherein a band gap energy of a semiconductor layer of a region in which light is propagated, in the region in which current is not injected into the active layer, is greater than the energy of the wavelength of the light that is emitted at the active layer.

6. The semiconductor laser device according to claim 1,
wherein the two active layers are constituted respectively by layers that include (AlₓGa₁₋ₓ)_{y}In_{1-y}P (where 0≦x≦1 and 0≦y≦1) and Al_{z}Ga_{1-z}As (where 0≦z≦1), and
wherein the wavelengths that are obtained from the two active layers are respectively at least 630 nm and at most 690 nm, and at least 760 nm and at most 810 nm.

7. The semiconductor laser device according to claim 6,
wherein the maximum light output that is emitted from a single facet that is obtained from the two active layers is at least 80 mW.

8. The semiconductor laser device according to claim 4,
wherein a band gap of at least one part of the quantum well active layer of at least one resonator, in the direction from one or both facets toward the center of the resonator is broadened by disordering through diffusion of impurities or injection of impurities,
wherein a current blocking layer is provided, or a part of the semiconductor layer or an electrode that corresponds to a current injection path is removed such that the current is not injected; and
wherein the length over which the process is performed, from the face toward the center of the resonator, differs between the two resonators.

9. The semiconductor laser device according to claim 1,
wherein the maximum light output obtained from the active layers respectively differs.

10. The semiconductor laser device according to claim 9,
wherein the at least two active layers are constituted by layers that include (AlₓGa₁₋ₓ)_{y}In_{1-y}P (where 0≦x≦1 and 0≦y≦1);
wherein, of the two active layers, the light output of the element with the higher maximum light output is at least 50 mW, and the operating current of the element with the lower output is at most 35 mA at a light power of at least 2 mW.

11. A method for manufacturing a semiconductor laser device, the method comprising:
a step of sequentially layering a first cladding layer of a first conductivity-type, a first active layer and a first cladding layer of a second conductivity-type on a substrate to form a first layered structure;
a step of removing the first layered structure from a predetermined region of the substrate;
a step of sequentially layering a second cladding layer of the first conductivity-type, a second active layer and a second cladding layer of the second conductivity-type above the substrate that includes the first layered structure to form a second layered structure;
a step of removing the second layered structure that is formed above the first layered structure;
a step of forming a layer made of an impurity diffusion source in a predetermined region above the first layered structure and the second layered structure; and
a step of heating the substrate and diffusing impurities from the layer that is made of an impurity diffusion source into the first layered structure and the second layered structure that are directly below it to disorder a part of at least either the first active layer or the second active layer,
wherein the resonator direction width of the region of the first layered structure into which impurities are diffused, and the resonator direction width of the region of the second layered structure into which impurities are diffused, are mutually different.

12. The method for manufacturing a semiconductor laser device according to claim 11,
wherein the width of the layer made of an impurity diffusion source in the resonator direction that is above the first layered structure is mutually different from that which is above the second layered structure.

13. The method for manufacturing a semiconductor laser device according to claim 11,
wherein in the resonators, the region of the first active layer into which a current is injected has a different length from the region of the second active layer into which a current is injected.

14. The method for manufacturing a semiconductor laser device according to claim 11,
wherein at least one of either the first active layer and the second active layer has a quantum well structure.

15. The method for manufacturing a semiconductor laser device according to claim 11,
wherein the wavelength of light that is emitted from the first active layer is mutually different from that which is emitted from the second active layer.

16. A method for manufacturing a semiconductor laser device, the method comprising:
a step of sequentially layering a cladding layer of a first conductivity-type, an active layer and a cladding layer of a second conductivity-type onto a substrate to form a layered structure;
a step of processing the cladding layer of the second conductivity-type to form at least two ridge stripe structures that are arranged in parallel; and
a step of diffusing impurities from above the layered structure that includes the at least two ridge stripe structures to disorder a part of the active layer that is directly below at least one of the ridge stripe structures;
wherein the resonator direction width of the region that is directly below one ridge stripe structure of the ridge stripe structures, in which the impurities are diffused, is mutually different from the resonator direction width of the region that is directly below an other ridge stripe structure, in which the impurities are diffused.

17. The method for manufacturing a semiconductor laser device according to claim 16,
wherein the length in the resonator direction of a gain region of the active layer that is directly below the one ridge stripe structure is mutually different from the length in the resonator direction of a gain region of the active layer that is directly below the other ridge stripe structure.
